(19) United States
(12) Patent Application Publication
(10) Pub. No.: US 2024/0201246 A1
(43) Pub. Date: Jun. 20, 2024

(54) METHOD FOR CHECKING A SIGNAL PATH OF AN ELECTRONIC SENSOR CIRCUIT FOR A FIELD DEVICE IN AUTOMATION TECHNOLOGY

(71) Applicant: Endress+Hauser SE+Co. KG, Maulburg (DE)

(72) Inventors: Stefan Müller, Emmendingen (DE); Dirk Dohse, Freiburg (DE); Manfred Hammer, Wehr (DE)

(21) Appl. No.: 18/554,657

(22) PCT Filed: Mar. 21, 2022
(86) PCT No.: PCT/EP2022/057298

§ 371 Date: Oct. 10, 2023

(30) Foreign Application Priority Data
Apr. 14, 2021 (DE) 10 2021 109 398.8

(51) Int. Cl. G01R 31/28; G01R 35/00

(52) U.S. Cl. CPC G01R 31/2829; G01R 31/2839; G01R 35/00

(57) ABSTRACT

A method for checking a signal path of a sensor circuit for a field device, wherein the signal path includes a transducer for outputting analog raw measured values, an analog-digital converter to convert the analog raw measured values into digital raw measured values, and a digital processor designed to further process the digital raw measured values, includes: interrupting the measuring mode; replacing the analog raw measured values at an output of the transducer by an analog check signal; passing the analog check signal through the signal path so that the digital processor determines a measured value corresponding to the analog check signal; checking the determined measured value with a comparison value determined for the signal path; and, if the measured value determined for the analog check signal is outside a defined tolerance range for the comparison value, identifying a change in the state of the signal path.

The invention relates to a method for checking a signal path of a sensor circuit for a field device in automation technology.

Field devices for recording and/or modifying process variables are often used in process automation, as well as in manufacturing automation. Measuring devices or sensors such as level measuring devices, flow meters, pressure and temperature measuring devices, pH-redox potential meters, conductivity meters, etc., are used for recording the respective process variables such as fill-level, flow, pressure, temperature, pH level, and conductivity. To influence process variables, actuators, such as, for example, valves or pumps, are used, via which the flow rate of a fluid in a pipeline section or a fill-level in a container can be altered by means of actuators.

The company group Endress+Hauser produces and distributes a large variety of such field devices.

Such field devices usually have an electronic sensor circuit, which are known per se. The electronic sensor circuit is used with the field devices to allow the additional processing of raw measured values, i.e., measured values that are not compensated, in particular not temperature-compensated. For example, a process variable in the form of raw measured values is acquired via an analog electrical transducer unit, and the analog raw measured values are digitized via an analog-digital converter in order to subsequently process the digitized raw measured values into (digital) measured values via a digital processor. In the process, a series of operations can be carried out with the raw measured values by means of the digital processor. For example, a temperature compensation of the raw measured values can be carried out to obtain a temperature-compensated digital output signal in the form of measured values. The processing of the analog raw measured value along the chain from the transducer element to the output of the digital processor is also referred to here as the signal path.

In practice, field devices in industrial plants are sometimes exposed to extreme conditions that can negatively affect the signal path over the lifetime of the electronic circuitry.

For example, extreme temperature fluctuations, vibrations, moisture or EMC can negatively influence the electrical or mechanical properties of the signal path and accordingly have a negative effect on the measurement function or the measurement accuracy.

The object of the invention is therefore to propose an option by means of which a signal path of an electronic circuit of a field device can be checked or monitored.

The object is achieved according to the invention by the method according to claim 1.

The method according to the invention for checking a signal path of an electronic sensor circuit for a field device in automation technology, wherein the sensor circuit comprises at least one signal path having at least one transducer element for detecting, converting and outputting a process variable to an output of the transducer element in the form of analog raw measured values, an analog-digital converter connected downstream from the transducer element to convert the analog raw measured values into digital raw measured values, and a digital processor, in particular a digital signal processor, downstream from the analog-digital converter which is fed the digitized raw measured values and is designed to further process the digitized raw measured values in a measuring mode to provide measured values, provides the following steps:
interrupting the measuring mode;
replacing the analog raw measured values at the output of the transducer element with an analog check signal;
passing the analog check signal through the signal path so that the digital processor determines a measured value corresponding to the analog check signal;
checking the determined measured value with a comparison value determined for the signal path, and if the measured value determined for the analog check signal is outside a defined tolerance range for the comparison value, identifying a change in the state of the signal path.

According to the invention, a method is proposed in which the analog raw measured values used in measuring mode for determining a measured value which originate from the transducer element are replaced by an analog check signal. This check signal therefore virtually represents a “simulated” signal which is then used for the elements of the signal path following the transducer element. Based on this check signal, the signal path is subsequently run through, and a measured value is determined analogously to the determination of a measured value in the actual measuring mode of the field device. This is then compared with a comparison value previously determined for the signal path such that, if there is a deviation greater than a tolerance range defined for the comparison value, a change in the state of the signal path is detected.

According to an advantageous embodiment, it can be provided that the comparison value determined for the signal path is determined during the production of the electronic sensor circuit and is accessed for checking the comparison value determined during the production of the electronic sensor circuit. In particular, the embodiment can provide that the comparison value determined during the manufacture of the electronic sensor circuit is stored in a memory element on the electronic sensor circuit.

According to an advantageous embodiment, it can be provided that the check signal applied to the output of the transducer element is realized by a voltage signal. In particular, the embodiment can provide that the voltage signal is generated by the digital processor.

According to an alternative embodiment, it can be provided that the voltage signal is generated with the aid of at least one capacitor provided on the electronic sensor circuit.

According to an advantageous embodiment, it can be provided that the replacement of the analog raw measured values at the output of the transducer element with the analog check signal is initiated or controlled by the digital processor or another digital processor.

According to an advantageous embodiment, it can be provided that the checking of the determined measured value with the comparison value determined for the signal path is carried out by the digital processor or another digital processor.

According to an advantageous embodiment, it can be provided that, in the event that a change in the state of the signal path is determined, this change is signaled.

According to an advantageous embodiment, it can be provided that after the check of the determined measured value with a comparison value determined for the signal path, measurement mode resumes, provided that the measured value determined for the analog check signal lies within the tolerance range defined for the comparison value.

According to another advantageous embodiment, it can be provided that before the analog verification signal passes through the signal path, the signal path is conditioned to the analog-digital converter, in particular a gain and/or offset is adjusted.

The invention is explained in more detail based upon the following drawing. In the FIGURES:

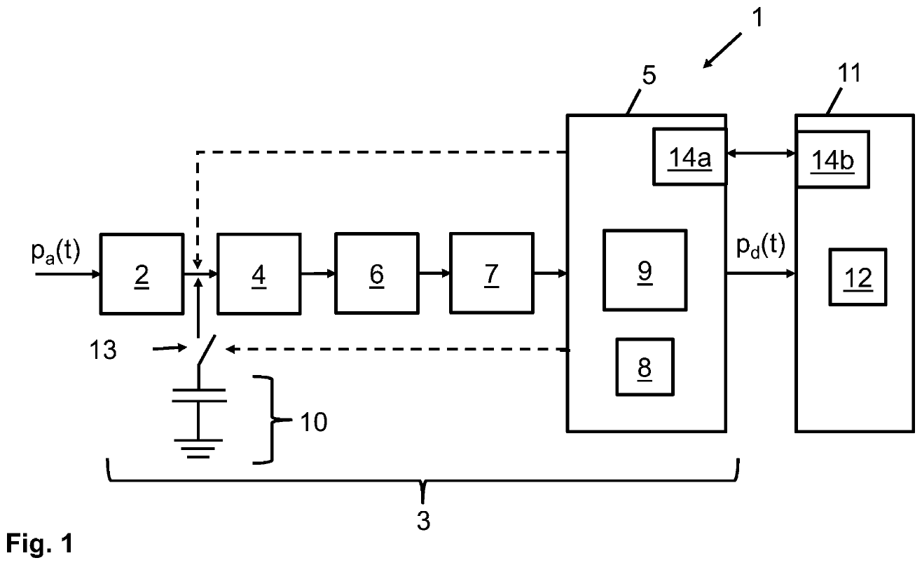

FIG. 1: shows a schematic representation of an electronic sensor circuit according to the invention for a field device in automation technology.

FIG. 1 shows an electronic sensor circuit 1 according to the invention for detecting analog raw measured values of a process variable, for example pressure measured values, and for processing the acquired raw measured values into a digital measured value. The electronic sensor circuit 1 comprises the following components: a transducer element 2 for detecting the process variable and converting the process variable into analog raw measured values, a pre-amplifier unit 4 for signal conditioning, an analog-digital converter 6 for converting the analog signal into a digital signal, and a digital processor 5, for example a digital signal processor for outputting the digital, in particular also compensated, measured values.

The components thereby form a signal path from the transducer element 2 to the digital processor 5. In addition to the transducer element 2 and the digital processor 5, the signal path must comprise at least the analog-digital converter 6 which converts the analog raw measured values originating from the transducer element 2 into digital raw measured values.

The transducer element is configured to detect a process variable in the form of raw measured values, and to output corresponding analog raw measured values, i.e., analog measured values which have not yet undergone compensation. The transducer element can be, for example, a pressure transducer element which has a temporally variable pressure pₐ(t) in the form of analog raw measured values. The invention is not limited to pressure transducer elements, but can also be transmitted to field devices with other transducer elements.

To perform conditioning, in particular a level adjustment of the signal coming from the transducer element, the signal path 3 can also comprise the preamplifier unit 4, as shown in FIG. 1. This is arranged in the signal path between the transducer element 2 and the analog-digital converter 6. By means of the conditioning, the signal originating from the transducer element is adapted to an input region of the downstream analog-digital converter 6; in particular gain and/or offset is adjusted.

The analog raw measured values are converted by the transducer element 2 into digital raw measured values by the analog-digital converter 6 arranged downstream from the preamplifier unit 4. For example, the analog-digital converter 6 can be designed as a 24-bit analog-digital converter.

Furthermore, the signal path can comprise at least one filter element 7. The component denoted by reference number 7 can be a hardware filter element 7, for example a SINC 3 filter element. The hardware filter element 7 is arranged in the signal path 3 between the analog-digital converter 6 and the digital processor 5 so that it filters the digitized raw measured values. Alternatively, the hardware filter element can also be implemented by an internal software filter element 9 on the digital processor.

The raw measured values digitized and possibly also filtered via the analog-digital converter 6 are supplied to the digital processor 5 for further processing. The processor 5 is configured to further process the digital raw measured values with the aid of an algorithm. In the process, a series of operations can be carried out with the raw measured values by means of the digital processor. For example, a temperature compensation of the raw measured values can be carried out, in order to obtain a temperature-compensated digital output signal in the form of measured values.

The electronic sensor circuit 1 described above can preferably be used in a field device of automation technology. For example, a media pressure can be converted by the transducer element of the sensor circuit of the field device into analog raw measured values which, as described above, are digitized by the sensor circuit and subsequently processed further into a compensated pressure measured value, for example by temperature compensation.

In order to check the signal path of the electronic sensor circuit and accordingly prevent a negative effect on the measurement function or the measurement accuracy in the actual measuring mode of the field device, the method according to the invention provides the following steps:

In a first step, the actual measuring mode is interrupted, i.e., no more analog raw measured values originating from the transducer element 2 are transmitted via the signal path. The interruption of the measuring mode can be initiated, for example, by the digital processor. Alternatively, however, the interruption can also be initiated by the additional processor 12 of the main electronics 11.

In a second step, the analog raw measured values at the output of the transducer element are replaced by an analog check signal. The check signal can, for example, be a voltage signal. The voltage signal can be generated either by the digital processor 5 itself or by means of a capacitor additionally provided on the electronic sensor circuit 1. In the event that the digital processor itself provides the voltage signal, it can be guided, as shown by way of example in FIG. 1 by a dashed line, from an output of the processor to the output of the transducer element. In the event that the voltage signal is generated with the aid of the capacitor, a “simulation” of the values at the output of the transducer element is virtually realized by the capacitor. For this purpose, the capacitor can be charged to a specific value, for example a maximum charge value, so that a voltage is generated across the capacitor, which voltage then serves as a voltage signal. Replacing the analog raw measured values at the output of the transducer element 2 can be realized by one or more switching elements 13 additionally provided on the sensor circuit. As shown in FIG. 1, this can take place by multiple individual (single-pole) switches or else by a multi-pole switch which switches between the voltage signal originating from an output of the processor 5, the voltage signal generated by means of the capacitor 10, and the analog raw measured value originating from the transducer element 2 in measuring mode. The switch element(s) can be controlled by the digital processor of the sensor circuit which, in the event that a check of the signal path is to take place, correspondingly activates the switching element 13 and thereby configures the sensor circuit 1 for the check. Alternatively, the switching element(s) 13 can also be activated by the additional digital processor 12 which is seated, for example, on main electronics 11 arranged apart from the sensor circuit 1. In FIG. 1, the activation of the switching element 13 by the digital processor 5 of the sensor electronics 1 is shown by way of example by a dashed arrow. In order for the sensor circuit 1 to communicate with the main electronics 11, they are designed complementary to one another, in particular digital communication sections 14a and 14b.

In a subsequent third step, the analog check signal passes through the signal path. This means that the analog check signal is conditioned by the pre-amplifier, if present, then converted into a digital signal by the analog-digital converter 6, filtered by the software or hardware filter element, if present, filtered and then processed further by the digital processor with the aid of the algorithm into a check value. The check signal therefore passes through the signal path in the same manner as the raw measured values originating from the transducer element in measuring mode.

In a subsequent fourth step, the previously determined check value is compared with a comparison value determined for the signal path 3. In the event that the check value determined for the analog check signal deviates from the comparison value by a predetermined amount, a change in the state of the signal path 3 is determined. This change in the state of the signal path 3 can then be signaled, for example by outputting an error message on a display of the field device.

The predetermined amount can either be predetermined by an operator, for example by corresponding configuration or parameterization of the field device or alternatively by the field device manufacturer, for example during the production of the field device or the electronic sensor circuit. The comparison value can, for example, be determined during the production of the electronic sensor circuit for exactly this signal path and can be used for the check which takes place later in the actual measuring mode. In order to be able to access the comparison value later, i.e., in the actual measuring mode, it can be stored or saved in a memory element 8 of the electronic sensor circuit during production. As shown in FIG. 1, the memory element 8 can be both a storage region of the digital processor and a separately formed storage component on the sensor electronics.

In a last step, the method provides that after checking the determined check value with a comparison value determined for the signal path, the electronic sensor circuit returns to the actual measuring mode, provided that the check value determined for the analog check signal does not deviate by the predetermined amount from the comparison value.

### LIST OF REFERENCE SIGNS

1 Electronic sensor circuit
2 Transducer element
3 Signal path
4 Pre-amplifier unit
5 Digital processor, especially digital signal processor
6 Analog-digital converter
7 Hardware filter element
8 Memory element
9 Software filter element
10 Capacitor
11 Main electronics
12 First digital processor
13 Switching element
14a, 14b Communications interface

1-11. (canceled)

12. A method for checking a signal path of an electronic sensor circuit for a field device in automation technology, wherein the sensor circuit includes the signal path having a transducer element for detecting, converting, and outputting a process variable to an output of the transducer element in the form of analog raw measured values, an analog-digital converter connected downstream from the transducer element to convert the analog raw measured values into digital raw measured values, and a digital processor, downstream from the analog-digital converter which is fed the digital raw measured values and the digital processor is designed to further process the digital raw measured values in a measuring mode into measured values, the method comprising:
interrupting the measuring mode;
replacing the analog raw measured values at the output of the transducer element with an analog check signal;
passing the analog check signal through the signal path so that the digital processor determines a measured value corresponding to the analog check signal;
checking the determined measured value with a comparison value determined for the signal path; and
identifying a change in a state of the signal path when the measured value determined for the analog check signal is outside a defined tolerance range for the comparison value.

13. The method according to claim 12, wherein the comparison value determined for the signal path is determined during the production of the electronic sensor circuit and is accessed for checking the comparison value determined during the production of the electronic sensor circuit.

14. The method according to claim 13, wherein the comparison value determined during the manufacture of the electronic sensor circuit is stored in a memory element on the electronic sensor circuit.

15. The method according to claim 12, wherein the check signal applied to the output of the transducer element is realized by a voltage signal.

16. The method according to claim 15, wherein the voltage signal is generated by the digital processor.

17. The method according to claim 15, wherein the voltage signal is generated with the aid of at least one capacitor provided on the electronic sensor circuit.

18. The method according to claim 12, wherein the replacement of the analog raw measured values at the output of the transducer element with the analog check signal is initiated or controlled by the digital processor or another digital processor.

19. The method according to claim 12, wherein the checking of the determined measured value with the comparison value determined for the signal path is carried out by the digital processor or another digital processor.

20. The method according to claim 12, further comprising:
signaling the change in the state of the signal path.

21. The method according to claim 12, further comprising:
resuming the measurement mode after the check of the determined measured value with the comparison value determined for the signal path when the measured value determined for the analog check signal lies within a tolerance range defined for the comparison value.

22. The method according to claim 12, further comprising:
conditioning the analog verification signal before the analog verification signal passes through the signal path, wherein the conditioning includes adjusting a gain and/or an offset.
